(19) United States
(12) Patent Application Publication
(10) Pub. No.: US 2010/0320616 A1
(43) Pub. Date: Dec. 23, 2010

(54) SEMICONDUCTOR DEVICE AND METHOD OF MANUFACTURING THE SAME

(75) Inventor: Hyung Jin PARK, Icheon-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/643,827

(22) Filed: Dec. 21, 2009

(30) Foreign Application Priority Data
Jun. 17, 2009 (KR) 10-2009-0053948

(51) Int. Cl. H01L 23/48; H01L 21/768

(52) U.S. Cl. 257/774; 438/666; 257/762; 257/E21.585; 257/E23.011

(57) ABSTRACT

A method of manufacturing a semiconductor device comprises forming an insulating layer on a semiconductor substrate, etching the insulating layer to form contact regions, forming a conductive layer on an entire surface including the contact regions, and spiking the conductive layer in the semiconductor substrate.

### CROSS-REFERENCE TO RELATED APPLICATION

Priority to Korean patent application number 10-2009-0053948, filed on Jun. 17, 2009, which is incorporated by reference in its entirety, is claimed.

### BACKGROUND OF THE INVENTION

The present invention relates to a semiconductor device and a method of manufacturing the same.

With the increasing integration of semiconductor devices, research is being carried out on improving the performance of devices as well as reducing the size of the devices. Today, most wiring processes in semiconductor devices are adopting a multi-layer wiring structure in order to overcome the difficulty in rapidly transferring a required signal using only a single wire when a highly integrated device operates.

Furthermore, in the process of manufacturing a multi-layer metal wiring of a semiconductor device, a tungsten (W) plug process is mainly used for making a connection between the transistors and metal wires or between metal wires. The tungsten (W) plug process includes; stacking a dielectric interlayer over a silicon substrate, patterning contact holes, deposition of tungsten (W) for preparing the connection with subsequent metal wires and chemical mechanical polishing (CMP).

In other semiconductor devices, a process of forming a copper (Cu) layer or an aluminum (Al) layer to provide connections between metal wires through contacts or vias is used.

In the manufacturing method of the above semiconductor device, an oxide layer may remain on the semiconductor substrate. This is due to the cleaning process or from native oxidization because the semiconductor substrate having the contacts or the vias formed therein is made of silicon. When the contacts are coupled to the silicon substrate with the remaining oxide layer therein, it becomes a problem in the high-speed operation of the semiconductor device. Furthermore, the Cu layer or the Al layer used to fill the contact holes can have a high contact resistance against the silicon substrate.

### BRIEF SUMMARY OF THE INVENTION

An embodiment of the invention is directed to providing a semiconductor device including a conductive layer spiked in a semiconductor substrate.

The conductive layer preferably is made of copper (Cu) or aluminum (Al).

The conductive layer preferably is spiked in the semiconductor substrate by a plasma treatment process.

The plasma treatment process preferably is performed in an atmosphere including an inert gas under process conditions having a temperature ranging from 100° C. to 500° C.

The semiconductor device preferably further comprises contacts, pads, or vias.

The conductive layer preferably has a number of wires having straightness.

The spiked conductive layer preferably is coupled with contacts.

In another aspect, there is provided a method of manufacturing a semiconductor device comprises forming a conductive layer spiked in a semiconductor substrate.

The conductive layer preferably is made of copper (Cu) or aluminum (Al).

The conductive layer preferably is spiked in the semiconductor substrate by a plasma treatment process.

The plasma treatment process preferably is performed in an atmosphere including an inert gas under process conditions having a temperature ranging from 100° C. to 500° C.

In yet another aspect, there is provided a method of manufacturing a semiconductor device comprises forming an insulating layer on a semiconductor substrate, etching the insulating layer to form contact regions, forming a conductive layer on an entire surface including the contact regions, and spiking the conductive layer in the semiconductor substrate.

The insulating layer preferably is an oxide layer or a nitride layer.

The conductive layer preferably is made of copper (Cu) or aluminum (Al).

The conductive layer preferably is spiked in the semiconductor substrate by a plasma treatment process.

The plasma treatment process preferably is performed in an atmosphere including an inert gas under process conditions having a temperature ranging from 100° C. to 500° C.

The method preferably further comprises cleaning the semiconductor substrate before forming the insulating layer on the semiconductor substrate.

The etching the-insulating-layer-to-form-contact-regions preferably comprises forming first contact regions by etching the insulating layer using a first contact region mask, depositing a first barrier metal on an entire surface including the first contact regions, forming a sacrificial layer on an entire surface including the first barrier metal, and forming second contact regions by etching the sacrificial layer using the is first contact region mask.

The first barrier metal preferably is Ti/TiN or Ti/TaN.

The method preferably further comprises, after forming the second contact regions, depositing a second barrier metal on an entire surface including the second contact regions.

The second barrier metal preferably is Ti/TiN or Ti/TaN.

The sacrificial layer preferably is made of phosphor-silicate glass (PSG) or boro-phospho-silicate glass (BPSG) material.

### BRIEF DESCRIPTION OF THE DRAWINGS

FIGS. 1a to 1g are sectional views illustrating a semiconductor device and a method of manufacturing the same according to an embodiment of the present invention.

### DESCRIPTION OF EMBODIMENTS

Hereinafter, an embodiment of the present invention is described with reference to the accompanying drawings.

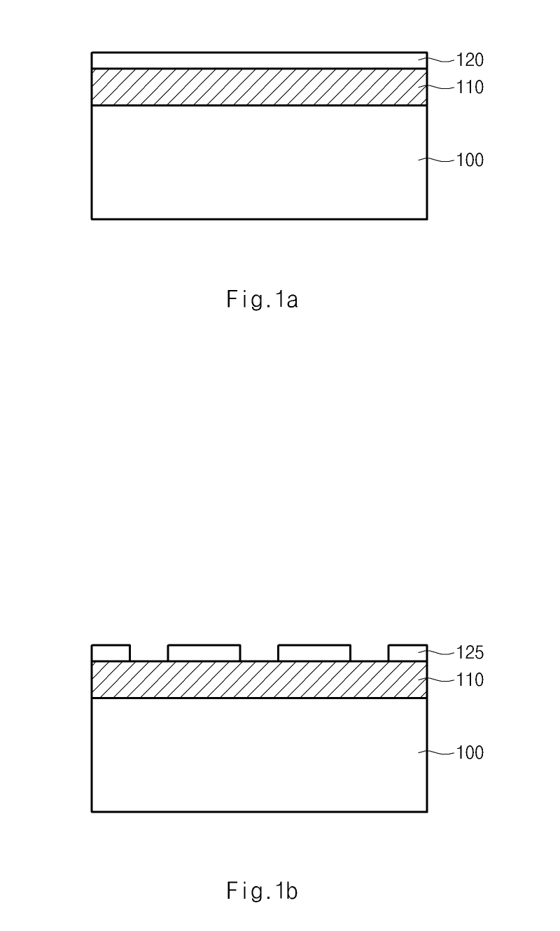

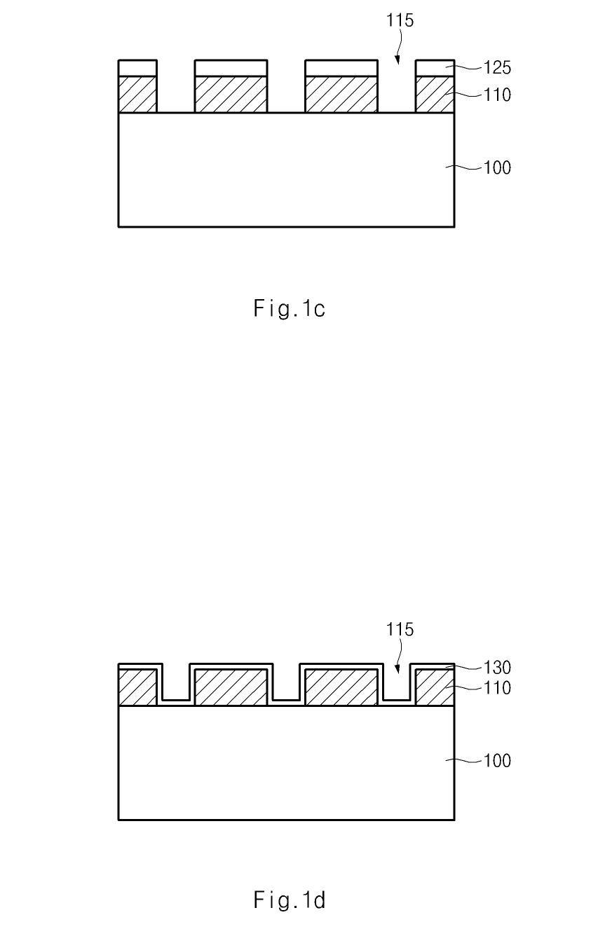

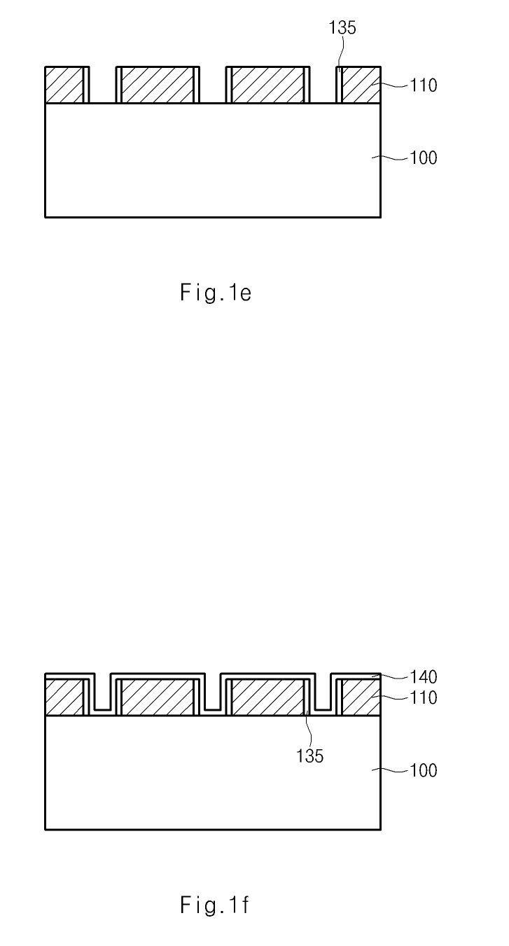

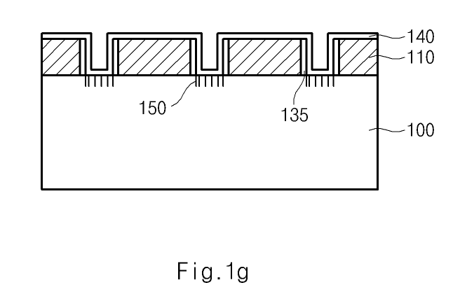

FIGS. 1a to 1g are sectional views illustrating a semiconductor device and a method of manufacturing the same according to an embodiment of the present invention.

Referring to FIGS. 1a and 1b, a semiconductor substrate 100 made of silicon is cleaned. An insulating layer 110 is deposited on the cleaned semiconductor substrate 100. The insulating layer 110 may be an oxide layer or a nitride layer functioning as a passivation layer.

A photoresist layer 120 is formed on the insulating layer 110. Exposure and development processes using a mask for forming contact regions are performed on the photoresist layer 120, thereby forming photoresist patterns 125. Here, a hard mask layer can be used instead of the photoresist layer 120. The photoresist layer 120 or the hard mask layer may be a nitride layer or an amorphous carbon layer. Although the photoresist patterns 125 have been formed using the mask for forming contact regions in the present embodiment, they can be formed using a mask for forming a number of semiconductor devices including pads, vias, etc. in another embodiment.

Referring to FIG. 1c, the underlying insulating layer 110 is etched using the photoresist patterns 125 as a mask, thereby forming contact region 115.

Referring to FIG. 1d, after removing the photoresist patterns 125, barrier metal 130 is deposited on the entire surface including the contact regions 115. The barrier metal 130 increases adhesion with the insulating layer 110 and may be formed from Ti/TiN or Ti/TaN.

Referring to FIG. 1e, an etch process is performed on the barrier metal 130 until the semiconductor substrate 100 is exposed. As a result of the etch process, the barrier metal 130 remains only on the sidewalls of the insulating layer 110 forming sidewall barrier metal 135.

Referring to FIG. 1f, a conductive layer 140 is formed on the entire surface including the contact regions 115. The conductive layer 140 may be a copper (Cu) layer or an aluminum (Al) layer in order to improve the interfacial characteristic of the contact faces between the semiconductor substrate 100 and the conductive layer 140.

Referring to FIG. 1g, a plasma treatment process is performed on the conductive layer 140 in an atmosphere including an inert gas under process conditions having a temperature ranging from 100° C. to 500° C. Argon (Ar) may be used as the inert gas. A conductive layer 150 having a spiked shape in the semiconductor substrate 100 is formed by the plasma treatment process. A thermal treatment process can be used instead of the plasma treatment process. The spiked shape conductive layer 150 has a plurality of wires. Accordingly, there is an advantage in that such a spike shape can improve the interfacial resistance at the contact area between the semiconductor substrate 100 and the conductive layer 150.

According to the present invention, the spiked shape conductive layer in the semiconductor substrate is formed. Accordingly, there is an advantage in that the electrical property and contact resistance with the semiconductor substrate can be improved.

The above embodiment of the present invention is illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device, comprising:
a semiconductor substrate; and
a conductive layer having a spiked shape in the semiconductor substrate, the conductive layer including metal.

2. The semiconductor device according to claim 1, wherein the conductive layer includes copper (Cu) or aluminum (Al), wherein copper or aluminum defines the spiked shape of the conductive layer.

3. The semiconductor device according to claim 1, wherein the spiked shape of the conductive layer is formed in the semiconductor substrate by applying a plasma treatment process.

4. The semiconductor device according to claim 3, wherein the plasma treatment process is performed in an atmosphere including an inert gas under process conditions having a temperature ranging from 100° C. to 500° C.

5. The semiconductor device according to claim 1, further comprising contacts, pads, or vias.

6. The semiconductor device according to claim 1, wherein the conductive layer has a plurality of metal components extending vertically, the metal components defining the spiked shape of the conductive layer.

7. The semiconductor device according to claim 1, wherein the conductive layer defines a trench configured to receive a contact plug.

8. A method of manufacturing a semiconductor device, comprising:
providing a semiconductor substrate;
forming a conductive layer having a spiked shape in the semiconductor substrate, the conductive layer including metal.

9. The method according to claim 8, wherein the conductive layer includes copper (Cu) or aluminum (Al), and

10. The method according to claim 8, wherein the conductive layer defines a trench directly over the contact region.

11. The method according to claim 8, wherein the conductive layer is spiked in the semiconductor substrate by a plasma treatment process.

12. The method according to claim 11, wherein the plasma treatment process is performed in an atmosphere including an inert gas under process conditions having a temperature ranging from 100° C. to 500° C.

13. A method of manufacturing a semiconductor device, comprising:
forming an insulating layer on a semiconductor substrate;
etching the insulating layer to form a trench that defines a contact region of the semiconductor substrate;
forming a conductive layer on over the insulting layer and within the trench; and
forming a plurality of spikes in the semiconductor substrate at the contact region, the spikes comprising metal.

14. The method according to claim 13, wherein the insulating layer includes oxide or nitride.

15. The method according to claim 13, wherein the conductive layer includes copper (Cu) or aluminum (Al).

16. The method according to claim 13, wherein spikes are formed in the semiconductor substrate by applying a plasma treatment process to the conductive layer.

17. The method according to claim 16, wherein the plasma treatment process is performed in an atmosphere including an inert gas under process conditions having a temperature ranging from 100° C. to 500° C.

18. The method according to claim 13, further comprising:
depositing a first barrier metal layer on surfaces of the trench;
is forming a sacrificial layer on the barrier metal; and
etching the sacrificial layer and the first barrier metal layer provided on a bottom surface of the trench to expose the contact region of the semiconductor region.

19. The method according to claim 18, wherein the first barrier metal layer includes Ti/TiN or Ti/TaN.

20. The method according to claim 18, further comprising:
depositing a second barrier metal layer within the trench after etching the sacrificial layer and the first barrier metal layer.

21. The method according to claim 20, wherein the second barrier metal includes Ti/TiN or Ti/TaN.

22. The method according to claim 18, wherein the sacrificial layer includes phosphor-silicate glass (PSG) or boro-phospho-silicate glass (BPSG) material.
